(19) United States
(12) Patent Application Publication
(10) Pub. No.: US 2023/0110529 A1
(43) Pub. Date: Apr. 13, 2023

(54) BLANK MASK AND PHOTOMASK USING THE SAME

(71) Applicant: SKC solmics Co., Ltd., Pyeongtaek-si (KR)

(72) Inventors: GeonGon LEE, Seoul (KR); Hahyeon CHO, Seoul (KR); INKYUN SHIN, Seoul (KR); Seong Yoon KIM, Seoul (KR); Suk Young CHOI, Seoul (KR); Hyung-joo LEE, Seoul (KR); Suhyeon KIM, Seoul (KR); SUNG HOON SON, Seoul (KR); Min Gyo JEONG, Seoul (KR); Taewan KIM, Seoul (KR)

(73) Assignee: SKC solmics Co., Ltd., Pyeongtaek-si (KR)

(21) Appl. No.: 17/960,214

(22) Filed: Oct. 5, 2022

(30) Foreign Application Priority Data
Oct. 7, 2021 (KR) 10-2021-0133001

(51) Int. Cl. G03F 1/46; G03F 1/32

(52) U.S. Cl. CPC G03F 1/46; G03F 1/32

(57) ABSTRACT

A blank mask including a transparent substrate and a light shielding film disposed on the transparent substrate, wherein the light shielding film comprises a transition metal and at least one selected from the group consisting of oxygen and nitrogen, and wherein when an optical density of the light shielding film is measured ten times by a light with a wavelength of 193 nm, a standard deviation of measured optical density is 0.009 or less, is disclosed.

### CROSS-REFERENCE TO RELATED APPLICATIONS

This application claims the benefit under 35 U.S.C. 119(a) of Korean Patent Application No. 10-2021-0133001 filed on Oct. 7, 2021 in the Korean Intellectual Property Office, the entire disclosure of which is incorporated herein by reference for all purposes.

### BACKGROUND

### 1. Field

The present disclosure relates to a blank mask and photomask using the same.

### 2. Description of Related Art

Due to high integration of semiconductor devices or the like, miniaturization of circuit patterns of semiconductor devices is being required. For this reason, the importance of a lithography technique, which is a technique for developing a circuit pattern on a wafer surface using a photomask, is being further emphasized.

To develop a miniaturized circuit pattern, a light source of exposure used in an exposure process (photolithography) is required to have a short wavelength. Recently, ArF excimer laser (wavelength of 193 nm) or the like is used as the light source of exposure.

On the other hand, there are Binary mask, Phase shift mask, and the like as photomasks.

The Binary mask has a structure in which a light shielding layer pattern is formed on a transparent substrate. A transmissive portion of the Binary mask not including a light shielding layer allows light for exposure to be transmitted on a surface, where a pattern is formed, whereas a light shielding portion of the Binary mask including a light shielding layer shields light for exposure, to transfer a pattern on resist film disposed on a wafer. However, the Binary mask may cause a problem in developing a minute pattern due to diffraction of light occurring at the edge of the transmissive portion as the pattern becomes more miniaturized.

There are Levenson type, Outrigger type, and Half-tone type as a phase shift mask. Among the above, Half-tone type phase shift mask has a structure, in which a pattern is formed with semi-transmissive films on a transparent substrate. On a surface, where a pattern is formed from the Half-tone type phase shift mask, a transmissive portion not including a semi-transmissive layer allows light for exposure to be transmitted, and a semi-transmissive portion including a semi-transmissive layer allows attenuated light for exposure to be transmitted. The attenuated light for exposure is allowed to have a phase difference compared to light, for exposure which has entered the transmissive portion. Accordingly, diffraction light occurring at the edge of the transmissive portion is counteracted by the light for exposure, which has transmitted the semi-transmissive portion, and thereby the phase shift mask can form a further refined minute pattern on the surface of a wafer.

### SUMMARY

A blank mask according to one embodiment of the present disclosure includes a transparent substrate and a light shielding film disposed on the transparent substrate.

The light shielding film may include a transition metal and at least one selected from the group consisting of oxygen and nitrogen.

When an optical density of the light shielding film is measured ten times by a light with a wavelength of 193 nm, a standard deviation of measured optical density values may be 0.009 or less.

A value obtained by subtracting a minimum value of the measured optical density values from a maximum value of the measured optical density values may be less than 0.03.

A surface of the light shielding film may have an Rsk value, which is a height skewness of the surface of the light shielding film, of -2 to 0.1.

The measured optical density values are the average values of optical density values measured at a total of 49 measuring points on the surface of the light shielding film, respectively.

A total of ten measured optical density values are obtained by repeating ten times of measuring at the total of 49 measuring points on the surface of the light shielding film, respectively, wherein, in each of the ten measurement, the total of 49 measuring points are same.

When a reflectance of the light shielding film is measured ten times by a light with a wavelength of 193 nm, a standard deviation of measured reflectance values may be 0.032% or less.

A value obtained by subtracting a minimum value of the measured reflectance values from a maximum value of the measured reflectance values may be 0.09% or less.

A reflectance value of the light shielding film with respect to a light with a wavelength of 190 nm to 550 nm may be 15% to 35%.

A Rku, which is kurtosis, of the surface of the light shielding film may be 3.5 or less.

A Rp, which is a maximum height of a peak, of the surface of the light shielding film may be 4.7 nm or less.

A Rpv, which is a sum of maximum height of a peak and maximum depth of a valley, of the surface of the light shielding film may be 8.5 nm or less.

The light shielding film may include a first light shielding layer and a second light shielding layer disposed on the first light shielding layer.

The second light shielding layer may have a greater amount of the transition metal than the first light shielding layer.

The transition metal may include at least one selected from the group consisting of Cr, Ta, Ti and Hf.

A photomask according to another embodiment of the present disclosure may include a transparent substrate and a light shielding pattern film disposed on the transparent substrate.

The light shielding pattern film may include a transition metal and at least one selected from the group consisting of oxygen and nitrogen.

When an optical density of an upper surface of the light shielding pattern film is measured ten times by a light with a wavelength of 193 nm, a standard deviation of measured optical density values may be 0.009 or less.

A value obtained by subtracting a minimum value of the measured optical density values from a maximum value of the measured optical density values may be less than 0.03.

The upper surface of the light shielding pattern film may have an Rsk value, which is a height skewness of the surface of the light shielding pattern film, of -2 to 0.1.

A method of manufacturing a blank mask according to another embodiment of the present disclosure may include: disposing a transparent substrate and a sputtering target inside a sputtering chamber; injecting an atmosphere gas into the sputtering chamber and supplying an electric power to the sputtering target to form a light shielding film on the transparent substrate; thermally treating the light shielding film; cooling the light shielding film; stabilizing the blank mask after the cooling operation in an atmosphere; and treating a surface of the light shielding film.

The treating the surface of the light shielding film may include a surface oxidation treatment process of applying an oxidizer solution to the surface of the light shielding film.

The method may further include a rinsing process of performing rinsing to the surface of the light shielding film.

The oxidizer solution may include at least one selected from the group consisting of a hydrogen water and SC-1 solution.

An amount of ammonia water within SC-1 solution may be 0.02 volume% to 2 volume% based on a total volume of the SC-1 solution.

The light shielding film may be thermally treated at a temperature of 160 to 300° C. for 5 to 30 minutes.

A method of manufacturing a semiconductor element according to another embodiment of the present disclosure includes: disposing a light source, a photomask, and a semiconductor wafer, on which a resist film have been applied, in a sputtering chamber; selectively transmitting a light incident from the light source onto the semiconductor wafer to be transferred; and developing a pattern on the semiconductor wafer.

The photomask includes a transparent substrate and a light shielding pattern film disposed on the transparent substrate.

The light shielding pattern film includes a transition metal and at least one selected from the group consisting of oxygen and nitrogen.

When an optical density of an upper surface of the light shielding pattern film is measured ten times by a light with a wavelength of 193 nm, a standard deviation of measured optical density values may be 0.009 or less.

A value obtained by subtracting a minimum value of the measured optical density values from a maximum value of the measured optical density values may be less than 0.03.

The upper surface of the light shielding pattern film may have an Rsk value, which is a height skewness of the surface of the light shielding pattern film, of -2 to 0.1.

Other features and aspects will be apparent from the following detailed description and the claims.

### BRIEF DESCRIPTION OF THE DRAWINGS

FIG. 1 is a conceptual view for illustrating a blank mask according to one embodiment disclosed in the present disclosure.

FIG. 2 is a conceptual view for illustrating a method for measuring optical density of a light shielding film.

FIG. 3 is a conceptual view for illustrating a blank mask according to another embodiment disclosed in the present disclosure.

FIG. 4 is a conceptual view for illustrating a blank mask according to another embodiment disclosed in the present disclosure.

FIG. 5 is a conceptual view for illustrating a photomask according to another embodiment disclosed in the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

In this disclosure, the term for degree like “about”, “substantially” and the like is used for meaning values approximative from/to the value when a tolerance proper to referred meaning for manufacture and substance is presented. Additionally, these terms for degree are used to help understanding of example embodiments and to prevent that an unconscionable trespasser unjustly uses the presented content in which exact or absolute number is referred.

Throughout this disclosure, the phrase “combination(s) thereof” included in a Markush-type expression denotes one or more mixtures or combinations selected from the group consisting of components stated in the Markush-type expression, that is, denotes one or more components selected from the group consisting of the components are included.

Throughout this disclosure, the description of “A and/or B” means “A, B, or A and B.”

Throughout this disclosure, terms such as “first”, “second”, “A”, or “B” are used to distinguish the same terms from each other unless specially stated otherwise.

In this disclosure, “B being placed on A” means that B is placed in direct contact with A or placed over A with another layer or structure interposed therebetween and thus should not be interpreted as being limited to B being placed in direct contact with A.

In this disclosure, a singular form is contextually interpreted as including a plural form as well as a singular form unless specially stated otherwise.

In this disclosure, the surface profile refers to an outward shape observed at a surface.

Rsk value is a value evaluated based on ISO_4287. Rsk value refers to the skewness of the surface profile of a measuring target.

Rku value is a value evaluated based on ISO4287. Rku value refers to the kurtosis of the surface profile of a measuring target.

Peak is a portion disposed on an upper portion of a reference line (refer to a height average line from a surface profile) from a surface profile of a light shielding film.

Valley is a portion disposed on a lower portion of a reference line from a surface profile of a light shielding film.

Rp value is a value evaluated based on ISO_4287. The Rp value is a maximum height of a peak within a surface profile of a measuring target.

Rv value is a value evaluated based on ISO_4287. The Rv value is a maximum depth of a valley within a surface profile of a measuring target.

Rpv value is a sum of Rp value and Rv value of a surface of a measuring target.

In this disclosure, the standard deviation refers to a sample standard deviation.

In this disclosure, pseudo-defects refer to one detected as a defect when inspected by highly sensitive defect test apparatus, even though not corresponding to a real defect because it does not cause degradation of the resolution of a blank mask.

Due to high integration of semiconductor devices or the like, miniaturization of circuit patterns of semiconductor devices is being required. For this reason, the importance of a lithography technique, which is a technique for developing a circuit pattern on a wafer surface using a photomask is being further emphasized.

For developing a minute circuit pattern elaborately on a semiconductor wafer, it may be required to control a light shielding pattern film of a photomask to have desired optical characteristics, and it may also be required to pattern the light shielding film elaborately to have a predesigned pattern shape.

Before a light shielding film in a blank mask is patterned, an optical property test may be performed for measuring optical density, reflectance, and the like of the light shielding film by using a spectroscopic ellipsometer. Also, after the formation of a light shielding film or a light shielding pattern film, a defect test may be performed. In a process of an optical property test, the measured value may be varied depending on each time of measurement and there may be a difficulty in specifying optical density, reflectance, and the like of a light shielding film. Additionally, in the process of a defect test, plural pseudo-defects may be detected, or a flare phenomenon may occur resulting from the surface characteristics of a light shielding film, and there may be a difficulty in detecting a real defect.

The inventors of the present disclosure confirmed that, when optical density of a light shielding film is measured plural times, the above problems can be solved by applying a blank mask showing a standard deviation regulated from measured values and skewness controlled on the surface of a light shielding film, and thereby completed the present disclosure.

Hereinafter, embodiments will be described in detail.

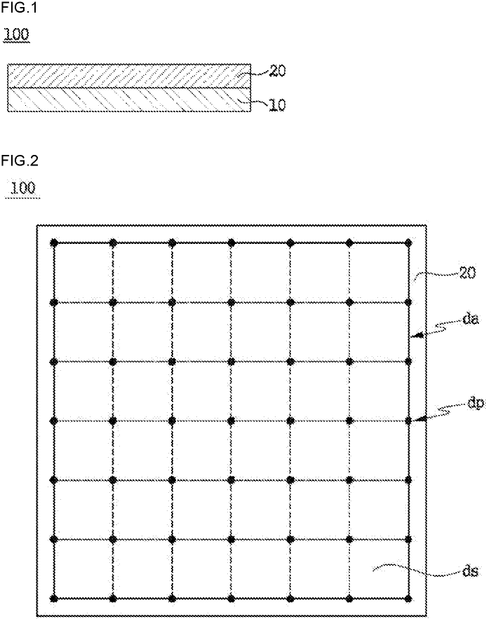

FIG. 1 is a conceptual view for illustrating a blank mask according to one embodiment disclosed in the present disclosure. With reference to the FIG. 1, a blank mask of an embodiment is described.

A blank mask 100 includes a transparent substrate 10 and a light shielding film 20 disposed on the transparent substrate 10.

Any material having light transmittance characteristic with respect to an exposure light to be applied to a blank mask is applicable as the material of a transparent substrate 10. In detail, the transmittance of a transparent substrate 10 with respect to an exposure light with a wavelength of 193 nm may be 85 % or more. The transmittance may be 87 % or more. The transmittance may be 99.99 % or less. For example, the transparent substrate 10 may be a synthetic quartz substrate. In such a case, the transparent substrate 10 can suppress attenuation of a light, which transmits the transparent substrate 10.

Additionally, the transparent substrate 10 can suppress the occurrence of optical distortion by regulating the surface characteristics such as smoothness and roughness.

The light shielding film 20 may be disposed on the top side of the transparent substrate 10.

The light shielding film 20 may have a characteristic of blocking at least some of an exposure light incident to the bottom side of the light transmitting substrate 10. Also, when a phase shift film 30 (refer to FIG. 4) is disposed between a light transmitting substrate 10 and a light shielding film 20, the light shielding film 20 may be used as an etching mask in a process of etching the phase shift film 30 to be a pattern shape.

The light shielding film 20 may includes a transition metal and at least any one between oxygen and nitrogen.

### Optical Properties of Light Shielding Film

When an optical density of the light shielding film 20 is measured ten times by a light with a wavelength of 193 nm, a standard deviation of measured values for optical density is 0.009 or less.

A value of subtracting the minimum value from the maximum value among the measured values for optical density is less than 0.03.

The optical density, reflectance, and the like of the light shielding film 20 after the formation can be measured by using a spectroscopic ellipsometer. In the process of measurement, when the light shielding film 20 is measured plural times in the same method, the deviation of measured values may be shown to be considerably large. This is thought as the result of the occurrence of diffused reflection of a testing light, which disturbs accurate measurement, on the surface of the light shielding film 20.

The embodiment may apply a light shielding film 20 regulated in the standard deviation of measured values obtained by measuring optical density plural times in the same method, and thereby enables easier and more accurate measurement of optical density values of a light shielding film 20.

A method of measuring the standard deviation of optical density values of the light shielding film 20 is deacribed below.

FIG. 2 is a conceptual view for illustrating a measuring method of optical density of a light shielding film. With respect to the FIG. 2, a blank mask of an embodiment is described.

On the light shielding film 20, a measuring area (da) of 132 mm vertically and horizontally disposed on the center of the light shielding film 20 is selected. The measuring area (da) is divided into six portions vertically and horizontally, and total 36 sectors (ds) are formed and selected. Total 49 vertices of the respective sectors (ds) are selected as measuring points (dp), and the transmittance value of the light shielding film 20 is measured at the measuring points. The optical density of Equation 1 below is calculated from the transmittance value.

$$O p t i c a l d e n s i t y = l o g \frac{100}{t r a n s m i t t a n c e \left(\%\right)}$$

By calculating the average value of optical density values of respective measuring points (dp), the calculated value is considered as the optical density value of the light shielding film 20.

The optical density of the light shielding film 20 is measured ten times in total, for calculating the standard deviation and a value of subtracting the minimum value from the maximum value among optical density values. All the processes of measuring the optical density of the light shielding film 20 ten times are performed at the same measuring points in the same measuring condition.

The optical density may be measured by using a spectroscopic ellipsometer. The wavelength of an inspection light is 193 nm. The spectroscopic ellipsometer may be for example, MG-Pro available from NANO-VIEW CO., LTD.

When the optical density of the light shielding film is measured ten times by a light with the wavelength of 193 nm, the standard deviation of the measured values for optical density may be 0.009 or less. The standard deviation may be 0.006 or less. The standard deviation may be 0.0055 or less. The standard deviation may be 0 or more.

A value of subtracting the minimum value from the maximum value among the measured optical density values may be less than 0.03. The value may be 0.025 or less. The value may be 0.02 or less. The value may be 0 or more.

In such a case, the optical density of the light shielding film 20 can be more accurately measured.

The optical density of the light shielding film with respect to a light with the wavelength of 193 nm may have a value of 1.5 to 3. The optical density of the light shielding film with respect to a light with the wavelength of 193 nm may have a value of 1.7 to 2.8. The optical density of the light shielding film with respect to a light with the wavelength of 193 nm may have a value of 1.8 to 2.5. In such a case, multilayer film including the light shielding film and phase shift film can block the exposure light effectively.

The transmittance of the light shielding film 20 with respect to a light with the wavelength of 193 nm may be 1% or more. The transmittance of the light shielding film 20 with respect to a light with the wavelength of 193 nm may be 1.3% or more. The transmittance of the light shielding film 20 with respect to a light with the wavelength of 193 nm may be 1.4% or more. The transmittance of the light shielding film 20 with respect to a light with the wavelength of 193 nm may be 2% or less. In such a case, the light shielding film 20 disposed on a phase shift film can help blocking of an exposure light effectively.

When the transmittance of the light shielding film 20 is measured ten times by a light with the wavelength of 193 nm, the standard deviation of measured values for transmittance may be 0.0018% or less. The value of subtracting the minimum value from the maximum value among the measured values for transmittance may be 0.0055% or less.

The method of measuring the standard deviation of the transmittance values and a value of subtracting the minimum value from the maximum value among transmittance values is the same as the method of measuring the standard deviation of optical densities and a value of subtracting the minimum value from the maximum value among optical density values, described above.

When the transmittance of a light shielding film 20 is measured ten times by a light with the wavelength of 193 nm, the standard deviation of measured values for transmittance may be 0.0018% or less. The standard deviation may be 0.0015% or less. The standard deviation may be 0.001% or less. The standard deviation may be 0% or more.

When the transmittance of a light shielding film 20 is measured ten times by a light with the wavelength of 193 nm, a value of subtracting the minimum value from the maximum value among measured values for transmittance may be 0.0055% or less. The value of subtracting the minimum value from the maximum value may be 0.0045% or less. The value of subtracting the minimum value from the maximum value may be 0.0035% or less. The value of subtracting the minimum value from the maximum value may be 0% or more.

In such a case, it may be easy to measure an accurate transmittance from a light shielding film 20 by using a spectroscopic ellipsometer.

When the reflectance of the light shielding film 20 is measured ten times by a light with the wavelength of 193 nm, the standard deviation of measured values for reflectance is 0.032% or less.

The value of subtracting the minimum value from the maximum value among the measured values for reflectance is 0.09% or less.

The method of measuring the reflectance values is the same as the method of measuring the optical density values, described above.

When the reflectance of the light shielding film 20 is measured ten times by a light with the wavelength of 193 nm, the standard deviation of measured values for reflectance may be 0.032% or less. The standard deviation may be 0.03% or less. The standard deviation may be 0.028% or less. The standard deviation may be 0% or more.

The value of subtracting the minimum value from the maximum value among the measured values for reflectance may be 0.09% or less. The value of subtracting the minimum value from the maximum value may be 0.0855% or less. The value of subtracting the minimum value from the maximum value may be 0.083% or less. The value of subtracting the minimum value from the maximum value may be 0% or more.

In such a case, it is possible to measure a more accurate reflectance value from the surface of the light shielding film 20.

The reflectance of the light shielding film 20 with respect to a light with a wavelength of 190 nm to 550 nm may be a value of 15% to 35%.

In the process of a defect test for the surface of the light shielding film 20, an inspection light is incident to the surface of the light shielding film 20 to form a reflectance light on the surface of the light shielding film 20. A defect tester can analyze the reflectance light and thereby can determine whether a defect is present. The embodiment can control the reflectance of the surface of the light shielding film 20 in the wavelength range of an inspection light of the defect tester. Through the above, it is possible to suppress deterioration in accuracy of a defect tester caused from the light intensity of a reflection light not controlled in the process of a defect test.

The reflectance of the light shielding film 20 is measured through a spectroscopic ellipsometer. The reflectance of the light shielding film 20 may be for example, measured by using MG-Pro model available from NANO-VIEW CO., LTD.

The light shielding film 20 may have a reflectance of 15% to 35% with respect to a light with a wavelength of 190 nm to 550 nm. The reflectance may have a value of 17% to 30%. The reflectance may have a value of 20% to 28%. In such a case, the accuracy of a defect test for the surface of the light shielding film 20 can be improved further.

### Characteristics Related to Surface Roughness of Light Shielding Film

The surface of a light shielding film 20 may have an Rsk (skewness) value of -2 to 0.1.

A measured value for optical properties of a light shielding film 20 of each measuring time may be varied depending on the characteristics in surface roughness of the light shielding film 20. In the process of reflecting and transmitting an inspection light on the surface of the light shielding film 20, peaks placed on the surface of the light shielding film may cause diffused reflection of the inspection light. This may affect the accuracy of a measured value for optical properties.

For suppressing the phenomenon of diffused reflection of an inspection light, a method of simply lowering the surface roughness of the light shielding film may be considered. However, in such a case, in the process of detecting a defect on the surface of the light shielding film 20, a flare phenomenon, which means incidence of a reflection light in an excessive intensity to a lens of a tester, may occur. The flare phenomenon may cause distortion of an image measured from the surface of the light shielding film, and may disturb detection of a real defect for the light shielding film 20.

The embodiment may control the composition, layer structure, process conditions for surface treatment of the light shielding film 20. At the same time, the surface profile of the light shielding film 20, and particularly, skewness can be controlled within a range predetermined in the embodiment. Through the above, the route of a reflection light may be controlled for being advantageous in obtaining a more accurately measured value when an optical property value is measured. In addition, in a process of detecting a defect, it is possible to suppress the occurrence of distortion in an image of the surface of the light shielding film, effectively.

A method of measuring Rsk value of the surface of the light shielding film is described below.

The Rsk value is measured at an area of 1 µm vertically and horizontally placed on the center of the surface of the light shielding film. The Rsk value is measured in Non-contact mode by using a two-dimensional roughness meter and setting the scan speed for the area to be 0.5 Hz. For example, XE-150 model available from Park System applied with PPP-NCHR as Cantilever model available from Park System may be applied to measure an Rsk value.

The surface of the light shielding film 20 may have an Rsk value of -2 to 0.1. The Rsk value may be -1 or more. The Rsk value may be -0.9 or more. The Rsk value may be -0.88 or more. The Rsk value may be -0.8 or more. The Rsk value may be -0.7 or more. The Rsk value may be 0 or less. The Rsk value may be -0.15 or less. The Rsk value may be -0.2 or less. In such a case, the degree of the occurrence of diffused reflection can be effectively decreased on the surface of the light shielding film 20.

The surface of the light shielding film 20 may have an Rku (kurtosis) value of 3.5 or less.

The embodiment may control the kurtosis distributed on the surface of the light shielding film 20. In such a case, in a process of measuring optical properties, it is possible to suppress dislocation from a desired light route for an inspection light reflected from the surface of the light shielding film. Additionally, excessively being increased is suppressed for the reflectance of the surface of the light shielding film 20, thereby improving the accuracy of a defect test.

A method of measuring an Rku value on the surface of the light shielding film 20 is the same as the method of measuring an Rsk value described above.

The surface of the light shielding film 20 may have an Rku value of 3.5 or less. The Rku value may be 3.2 or less. The Rku value may be 3 or less. The Rku value may be 1 or more. The Rku value may be 2 or more. In such a case, it is possible to help suppressing the occurrence of diffused reflection on the surface of the light shielding film 20, and it is possible to help the light shielding film to show a reflectance suitable to a defect test.

The embodiment can control the maximum height of a peak or the maximum depth of a valley placed on the surface of the light shielding film 20. Through the above, it is possible to make an inspection light reflected from the surface of the light shielding film 20 have intensity sufficient for detecting a defect, and the frequency of detecting a pseudo-defect can be remarkably reduced. Also, the deviation of measured values can be decreased when an optical property value is measured.

A measuring method of Rp (maximum height of a peak) and Rv (maximum depth of a valley) values on the surface of the light shielding film 20 is the same as the method of measuring an Rsk value described above. The Rpv (sum of maximum height of a peak and maximum depth of a valley) value is calculated by sum of an Rp value and an Rv value.

The surface of the light shielding film 20 may have an Rp value of 4.7 nm or less. The Rp value may be 4.65 nm or less. The Rp value may be 4.5 nm or less. The Rp value may be 1 nm or more.

The surface of the light shielding film 20 may have an Rv value of 3.9 nm or less. The Rv value may be 3.6 nm or less. The Rv value may be 3.5 nm or less. The Rv value may be 1 nm or more.

The surface of the light shielding film 20 may have an Rpv value of 8.5 nm or less. The Rpv value may be 8.4 nm or less. The Rpv value may be 8.3 nm or less. The Rpv value may be 8 nm or less. The Rpv value may be 7.9 nm or less. The Rpv value may be 1 nm or more.

In such a case, it is possible to improve the accuracy of the measurement in defects and optical properties of the surface of the light shielding film 20.

### Layer Structure and Composition of Light Shielding Film

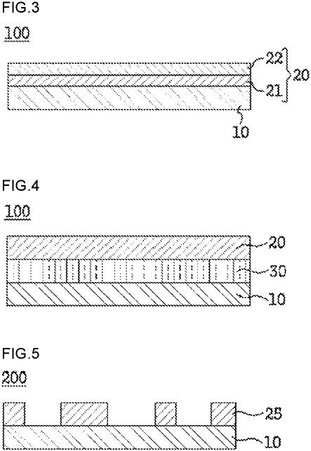

FIG. 3 is a conceptual view for illustrating a blank mask according to another embodiment of the present disclosure. With reference to the FIG. 3, an embodiment is described.

The light shielding film 20 may include a first light shielding layer 21 and a second light shielding film 22 disposed on the first light shielding layer 21.

The second light shielding layer 22 may include a transition metal and at least any one between oxygen and nitrogen. The second light shielding layer 22 may include a transition metal in an amount of 35 at% or more. The second light shielding layer 22 may include a transition metal in an amount of 40 at% or more. The second light shielding layer 22 may include a transition metal in an amount of 45 at% or more. The second light shielding layer 22 may include a transition metal in an amount of 50 at% or more. The second light shielding layer 22 may include a transition metal in an amount of 75 at% or less. The second light shielding layer 22 may include a transition metal in an amount of 70 at% or less. The second light shielding layer 22 may include a transition metal in an amount of 65 at% or less. The second light shielding layer 22 may include a transition metal in an amount of 60 at% or less.

The amount of elements corresponding to oxygen or nitrogen of the second light shielding layer 22 may be 15 at% or more. The amount may be 20 at% or more. The amount may be 25 at% or more. The amount may be 55 at% or less. The amount may be 50 at% or less. The amount may be 45 at% or less.

The second light shielding layer 22 may include oxygen in an amount of 5 at% or more. The second light shielding layer 22 may include oxygen in an amount of 10 at% or more. The second light shielding layer 22 may include oxygen in an amount of 25 at% or less. The second light shielding layer 22 may include oxygen in an amount of 20 at% or less.

The second light shielding layer 22 may include nitrogen in an amount of 10 at% or more. The second light shielding layer 22 may include nitrogen in an amount of 15 at% or more. The second light shielding layer 22 may include nitrogen in an amount of 30 at% or less. The second light shielding layer 22 may include nitrogen in an amount of 25 at% or less.

The second light shielding layer 22 may include carbon in an amount of 1 at% or more. The second light shielding layer 22 may include carbon in an amount of 3 at% or more. The second light shielding layer 22 may include carbon in an amount of 10 at% or less. The second light shielding layer 22 may include carbon in an amount of 8 at% or less.

In such a case, it is possible to help a light shielding film 20 and a phase shift film 30 to form a laminate together and block an exposure light substantially.

The first light shielding layer 21 may include a transition metal, oxygen, and nitrogen. The first light shielding layer 21 may include a transition metal in an amount of 20 at% or more. The first light shielding layer 21 may include a transition metal in an amount of 25 at% or more. The first light shielding layer 21 may include a transition metal in an amount of 30 at% or more. The first light shielding layer 21 may include a transition metal in an amount of 55 at% or less. The first light shielding layer 21 may include a transition metal in an amount of 50 at% or less. The first light shielding layer 21 may include a transition metal in an amount of 45 at% or less.

The sum of the oxygen amount and the nitrogen amount of the first light shielding layer 21 may be 22 at% or more. The sum of the oxygen amount and the nitrogen amount of the first light shielding layer 21 may be 30 at% or more. The sum of the oxygen amount and the nitrogen amount of the first light shielding layer 21 may be 40 at% or more. The sum of the oxygen amount and the nitrogen amount of the first light shielding layer 21 may be 70 at% or less. The sum of the oxygen amount and the nitrogen amount of the first light shielding layer 21 may be 60 at% or less. The sum of the oxygen amount and the nitrogen amount of the first light shielding layer 21 may be 50 at% or less.

The first light shielding layer 21 may include oxygen in an amount of 20 at% or more. The first light shielding layer 21 may include oxygen in an amount of 25 at% or more. The first light shielding layer 21 may include oxygen in an amount of 30 at% or more. The first light shielding layer 21 may include oxygen in an amount of 50 at% or less. The first light shielding layer 21 may include oxygen in an amount of 45 at% or less. The first light shielding layer 21 may include oxygen in an amount of 40 at% or less.

The first light shielding layer 21 may include nitrogen in an amount of 2 at% or more. The first light shielding layer 21 may include nitrogen in an amount of 5 at% or more. The first light shielding layer 21 may include nitrogen in an amount of 20 at% or less. The first light shielding layer 21 may include nitrogen in an amount of 15 at% or less.

The first light shielding layer 21 may include carbon in an amount of 5 at% or more. The first light shielding layer 21 may include carbon in an amount of 10 at% or more. The first light shielding layer 21 may include carbon in an amount of 25 at% or less. The first light shielding layer 21 may include carbon in an amount of 20 at% or less.

In such a case, the first light shielding layer 21 can help the light shielding film 20 to have an excellent extinction characteristic.

The transition metal may include at least one selected from the group consisting of Cr, Ta, Ti, and Hf. The transition metal may be Cr.

The first light shielding layer 21 may have a thickness of 250 to 650 Å. The first light shielding layer 21 may have a thickness of 350 to 600 Å. The first light shielding layer 21 may have a thickness of 400 to 550 Å. In such case, the first light shielding layer 21 can help the light shielding film 20 to block an exposure light effectively.

The second light shielding layer 22 may have a thickness of 30 to 200 Å. The second light shielding layer 22 may have a thickness of 30 to 100 Å. The second light shielding layer 22 may have a thickness of 40 to 80 Å. In such a case, the second light shielding layer 22 can improve the extinction characteristic of the light shielding film 20 and can help the side surface profile of a light shielding pattern film, which is formed by patterning the light shielding film 20, to be more elaborately controlled.

The thickness of the second light shielding layer 22 to the thickness of the first light shielding layer 21 may have a ratio of 0.05 to 0.3. The thickness ratio may be equal to or more than 0.07 and less than or equal to 0.25. The thickness ratio may be equal to or more than 0.1 and less than or equal to 0.2. In such a case, a light shielding pattern film formed from the light shielding film 20 can have a side surface profile close to be perpendicular from a surface of the transparent substrate and the light shielding film 20 may have a sufficient extinction characteristic.

The amount of a transition metal of the second light shielding layer 22 may be greater than the amount of a transition metal of the first light shielding layer 21.

For elaborately controlling the side surface profile of a light shielding pattern film and for controlling a reflectance suitable for a defect test, a second light shielding layer 22 may have a greater amount of a transition metal, compared to a first light shielding layer 21. However, in such a case, recovery, recrystallization, and the growth of a grain of a transition metal may occur in the second light shielding layer 22 caused from thermal treatment of a light shielding film 20. When the growth of a grain is not controlled in the second light shielding layer, in which a transition metal has been included in a high amount, the surface of the light shielding film 20 may form a deformed outline due to transition metal grain grown excessively, compared to the thermal treatment. This may cause a change in roughness characteristics of the light shielding film 20, and may affect the measurement of optical properties and the accuracy of a defect test for the light shielding film 20.

The embodiment can control the roughness characteristics, the process conditions in thermal treatment, cooling treatment and surface treatment, and the like of the light shielding film 20, while controlling the amount of a transition metal of the second light shielding layer 22 to be greater than the amount of a transition metal of the first light shielding layer 21 at the same time. Through the above, it is possible to obtain more accurately measured value for optical properties and the result of a defect test from the surface of the light shielding film 20, while allowing the light shielding film 20 to have desired optical properties and etching characteristics.

### Other Thin Film

FIG. 4 is a conceptual view for illustrating a blank mask according to another embodiment of the present disclosure. With reference to the FIG. 4, a blank mask of an embodiment is described.

A blank mask 100 according to another embodiment of the present disclosure includes a transparent substrate 10, a phase shift film 30 disposed on the transparent substrate 10 and a light shielding film 20 disposed on the phase shift film 30.

The phase shift film 30 includes a transition metal and silicon.

The description of the light shielding film 20 is overlapped with the above description and thus the further description is omitted.

The phase shift film 30 may be disposed between the transparent substrate 10 and the light shielding film 20. The phase shift film 30 is a thin film, which attenuates the light intensity of an exposure light transmitting the phase shift film 30 and regulates a phase difference, thereby substantially suppressing a diffraction light occurring at the edge of a pattern.

The phase shift film 30 may have a phase difference of 170 to 190° with respect to a light with the wavelength of 193 nm. The phase shift film 30 may have a phase difference of 175 to 185° with respect to a light with the wavelength of 193 nm. The phase shift film 30 may have a transmittance of 3 to 10% with respect to a light with the wavelength of 193 nm. The phase shift film 30 may have a transmittance of 4 to 8% with respect to a light with the wavelength of 193 nm. In such a case, the resolution of a photomask, in which the phase shift film 30 has been included, can be improved.

The phase shift film 30 may include a transition metal and silicon. The phase shift film 30 may include a transition metal, silicon, oxygen, and nitrogen. The transition metal may be molybdenum.

The descriptions of the properties and composition of the light transmitting substrate 10 and the light shielding film 20 are overlapped with the above descriptions, respectively, and thus the further description is omitted.

A hard mask (not shown) may be placed on the light shielding film 20. The hard mask may function as an etching mask film when the light shielding film is etched. The hard mask may include silicon, nitrogen, and oxygen.

### Photomask

FIG. 5 is a conceptual view for illustrating a photomask according to another embodiment of the present disclosure. With reference to the FIG. 5, a photomask of an embodiment is described.

A photomask according to another embodiment of the present disclosure includes a transparent substrate 10 and a light shielding pattern film 25 disposed on the transparent substrate 10.

The light shielding pattern film 25 may include a transition metal and at least any one between oxygen and nitrogen.

When an optical density of an upper surface of the light shielding pattern film 25 is measured ten times by a light with a wavelength of 193 nm, a standard deviation of measured values for optical density is 0.009 or less.

A value of subtracting the minimum value from the maximum value among the measured values for optical density is less than 0.03.

The upper surface of the light shielding pattern film 25 has an Rsk (skewness) value of -2 to 0.1.

The light shielding pattern film 25 may be formed by patterning the light shielding film 20 of the blank mask 100 described above.

A method of measuring an optical density of the light shielding pattern film 25 is the same as the method of measuring an optical density of the light shielding film described above. However, when a measuring point is not placed on the upper surface of the light shielding pattern film 25, the optical density is measured after resetting the position of a measuring point on the upper surface of the light shielding pattern film placed near to the measuring point.

A method of measuring an Rsk value on the upper surface of the light shielding pattern film 25 is the same as the method of measuring an Rsk value of the surface of the light shielding film 20 described above. However, when the upper surface of the light shielding pattern film 25 is not placed in an area of 1 µm vertically and horizontally placed on the center of the surface of the photomask 200, the measurement is performed for the upper surface of the light shielding pattern film 25 placed near to the above area.

The description of the properties, composition and structure of the light shielding pattern film 25 is overlapped with the description of the light shielding film 20 of the blank mask 100 and thus the further description is omitted.

### Manufacturing Method of Light Shielding Film

A manufacturing method of a blank mask according to one embodiment of the present disclosure may include preparation of disposing a transparent substrate and a sputtering target inside a sputtering chamber.

A manufacturing method of a blank mask according to one embodiment of the present disclosure may include a film formation operation of injecting an atmosphere gas into a sputtering chamber and supplying an electric power to a sputtering target to form a light shielding film on the light transmitting substrate.

The film formation operation may include a first light shielding layer formation process of forming a first light shielding layer on the transparent substrate; and a second light shielding layer formation process of forming a second light shielding layer on the first light shielding layer.

A manufacturing method of a blank mask according to one embodiment of the present disclosure may include a thermal treatment operation of thermally treating for a time of 5 minutes to 30 minutes in an atmosphere at a temperature of 150° C. to 300° C.

A manufacturing method of a blank mask according to one embodiment of the present disclosure may include a cooling operation of cooling a light shielding film after the thermal treatment operation.

A manufacturing method of a blank mask according to one embodiment of the present disclosure may include a stabilization operation of stabilizing the blank mask after the cooling operation in an atmosphere at a temperature of 10° C. to 60° C.

A manufacturing method of a blank mask according to one embodiment of the present disclosure may include a surface treatment operation of treating the surface of the light shielding film of the blank mask after the stabilization operation.

The surface treatment operation may include a surface oxidation treatment process of applying an oxidizer solution to the surface of the light shielding film.

The surface treatment operation may include a rinsing process of performing rinsing to the surface of the light shielding film.

In the preparation, a target may be selected considering the composition of the light shielding film. A sputtering target may be one target containing a transition metal. The sputtering target may be two or more targets including one target containing a transition metal. The target containing a transition metal may include a transition metal in an amount of 90 at% or more. The target containing a transition metal may include a transition metal in an amount of 95 at% or more. The target containing a transition metal may include a transition metal in an amount of 99 at% or more.

The transition metal may include at least one selected from the group consisting of Cr, Ta, Ti and Hf. The transition metal may include Cr. The transition metal may be Cr.

The description of the transparent substrate disposed inside the sputtering chamber overlaps with the above description and omitted.

A magnet may be disposed at the sputtering chamber in preparation. The magnet may be disposed on the surface opposite to one surface, where sputtering occurs from a sputtering target.

In the light shielding film formation operation, when films are formed by layers included in the light shielding film, the process condition for film formation may be applied to be different from each layer. Particularly, various process conditions such as the composition of an atmosphere gas, the electric power supplied to a sputtering target, and the time for film formation may be applied to be different from each layer, in consideration of the characteristics of surface roughness, extinction, etching, and the like.

The atmosphere gas may include an inert gas, a reactive gas, and a sputtering gas. The inert gas is a gas not including an element constituting a formed thin film. The reactive gas is a gas including an element constituting a formed thin film. The sputtering gas is a gas colliding with a target by being ionized in a plasma atmosphere.

The inert gas may include helium.

The reactive gas may include a gas including a nitrogen element. The gas including a nitrogen element may be for example, N₂, NO, NO₂, N₂O, N₂O₃, N₂O₄, N₂O₅ or the like. The reactive gas may include a gas including an oxygen element. The gas including an oxygen element may be for example, O₂, CO₂ or the like. The reactive gas may include a gas including a nitrogen element and a gas including an oxygen element. The reactive gas may include a gas including both nitrogen element and oxygen element. The gas including both nitrogen element and oxygen element may be for example, N₂, NO, NO₂, N₂O, N₂O₃, N₂O₄, N₂O₅ or the like.

The sputtering gas may be Ar gas.

The power source for supplying an electric power to a sputtering target may be DC power source, or RF power source.

In the first light shielding layer formation process, the electric power supplied to a sputtering target may be 1.5 kW to 2.5 kW. In the first light shielding layer formation process, the electric power supplied to a sputtering target may be 1.6 kW to 2 kW.

In the first light shielding layer formation process, the flow rate of a reactive gas to the flow rate of an inert gas within an atmosphere gas may have a ratio of 1.5 to 3. The flow rate ratio may be equal to or more than 1.8 and less than or equal to 2.7. The flow rate ratio may be equal to or more than 2 and less than or equal to 2.5.

The oxygen amount to the nitrogen amount included in the reactive gas may have a ratio of 1.5 to 4. The oxygen amount to the nitrogen amount included in the reactive gas may have a ratio of 2 to 3. The oxygen amount to the nitrogen amount included in the reactive gas may have a ratio of 2.2 to 2.7.

In such a case, a first light shielding layer can help the light shielding film to have a sufficient extinction characteristic, and the etching characteristic of the first light shielding layer can be controlled and thereby it is possible to help the side surface profile of the light shielding pattern after being patterned to have a shape close to be perpendicular from a surface of the transparent substrate.

The time for film formation of the first light shielding layer may be equal to or more than 200 seconds and less than or equal to 300 seconds. The time for film formation of the first light shielding layer may be equal to or more than 210 seconds and less than or equal to 240 seconds. In such a case, the first light shielding layer can help the light shielding film to have a sufficient extinction characteristic.

After the formation of the first light shielding layer is performed, supplying an electric power and an atmosphere gas into a sputtering chamber is suspended for a time of 5 seconds to 10 seconds, and the electric power and the atmosphere gas may be supplied again in a second light shielding layer formation process.

In the second light shielding layer formation process, the electric power supplied to a sputtering target may be 1 kW to 2 kW. In the second light shielding layer formation process, an electric power of 1.2 kW to 1.7 kW may be applied to a sputtering target.

In the second light shielding layer formation process, the flow rate of a reactive gas to the flow rate of an inert gas may have a ratio of 0.3 to 0.8. The flow rate ratio may be equal to or more than 0.4 and less than or equal to 0.6.

In the second light shielding layer formation process, the oxygen amount to the nitrogen amount included in the reactive gas may have a ratio of 0.3 or less. The oxygen amount to the nitrogen amount included in the reactive gas may have a ratio of 0.1 or less. The oxygen amount to the nitrogen amount included in the reactive gas may have a ratio of 0.0001 or more

In such a case, it is possible to help control the surface roughness characteristic of the light shielding film within a range targeted in the embodiment, and it is possible to help the light shielding film to have a stable extinction characteristic.

The time for film formation of the second light shielding layer may be equal to or more than 10 seconds and less than or equal to 30 seconds. The time for film formation of the second light shielding layer may be equal to or more than 15 seconds and less than or equal to 25 seconds. In such a case, the second light shielding layer is included in the light shielding film and can help suppressing transmission of an exposure light.

In the thermal treatment operation, a light shielding film after the film formation operation may be thermally treated. In detail, the substrate after the formation of the light shielding film is disposed in a thermal treatment chamber, and after that the thermal treatment may be performed.

The light shielding film is thermally treated to reduce a stress formed in the light shielding film and can improve the density of the light shielding film further. When thermal treatment is applied to the light shielding film, a transition metal included in the light shielding film may pass through recovery and recrystallization processes, and the stress formed in the light shielding film can be effectively reduced. However, in the thermal treatment operation, when the process conditions such as temperature and time for thermal treatment are not controlled, metal grain growth occur in the light shielding film, and due to transition metal grains not controlled in the size, the surface profile of the light shielding film may be considerably deformed compared to the surface profile before the thermal treatment. This may affect the surface roughness characteristic of the light shielding film, and may cause a problem in processes of measuring optical properties and defects on the surface of the light shielding film.

The embodiment controls the time and temperature for thermal treatment in the thermal treatment operation, and controls the speed, time, and atmosphere gas for cooling in the cooling operation described in detail below. Thereby the embodiment can make the surface of the light shielding film have a roughness characteristic predetermined in the embodiment, while removing the inner stress formed in the light shielding film effectively, and can help a defect test and obtaining accurate measured values for optical properties from the light shielding film.

The thermal treatment operation may be performed at a temperature of 160 to 300° C. The thermal treatment operation may be performed at a temperature of 190 to 280° C.

The thermal treatment operation may be performed for a time of 5 to 30 minutes. The thermal treatment operation may be performed for a time of 10 to 20 minutes.

In such a case, it is possible to reduce the internal stress formed in the light shielding film effectively, and it is possible to help suppressing the excessive growth of a transition metal grain caused from thermal treatment.

In the cooling operation, the light shielding film after thermal treatment may be cooled. To the side of the transparent substrate of the blank mask after the thermal treatment operation, a cooling plate regulated to have a cooling temperature predetermined in the embodiment is disposed to cool a blank mask. In the cooling operation, distance between a blank mask and a cooling plate is regulated, process conditions such as introducing an atmosphere gas is applied, and thereby the cooling speed of a blank mask can be controlled.

For the blank mask, the cooling operation may be within 2 minutes after completion of the thermal treatment operation. In such a case, it is possible to prevent the growth of a transition metal grain caused from residual heat inside the light shielding film.

Pins having a regulated length are equipped in respective sides of the cooling plate, subsequently a blank mask is disposed to allow the transparent substrate on the pins to face the cooling plate, and the cooling speed of the blank mask can be controlled.

In addition to the cooling method by the cooling plate, an inert gas may be injected into atmosphere where the cooling operation is performed for cooling the blank mask. In such a case, the residual heat in the side of the light shielding film of the blank mask, whose cooling efficiency of the cooling plate is slightly low, can be more effectively removed.

The inert gas may be for example, helium.

In the cooling operation, the cooling temperature applied to the cooling plate may be a temperature of 10 to 30° C. The cooling temperature may be a temperature of 15 to 25° C.

In the cooling operation, the distance between the blank mask and the cooling plate may be 0.01 to 30 mm. The distance may be 0.05 to 5 mm. The distance may be 0.1 to 2 mm.

In the cooling operation, the cooling speed of the blank mask may be 30 to 80° C./min. The cooling speed may be 35 to 75° C./min. The cooling speed may be 40 to 70° C./min.

In such a case, the grain growth of a transition metal caused from heat remaining in the light shielding film after thermal treatment may be suppressed and it is possible to help the surface of the light shielding film to have a surface roughness characteristic within a range predetermined in the embodiment.

In the stabilization operation, the blank mask after the cooling operation may be stabilized. Through this, damage of the blank mask caused from a rapid change of temperature can be prevented.

Various method may be used for stabilizing the blank mask after the cooling operation. As one example, the blank mask after cooling operation may be detached from the cooling plate and may be left for a certain time at a room temperature. As another example, the blank mask after the cooling operation is detached from the cooling plate and may be stabilized for a time of 30 minutes to 200 minutes in an atmosphere at a temperature of 15° C. to 30° C. At this time, the blank mask may be rotated at a rate of 20 rpm to 50 rpm. As another example, a gas not reacting with a blank mask may be injected to the blank mask after the cooling operation for a time of 1 minute to 5 minutes. At this time, the gas not reacting with a blank mask may have a temperature of 20° C. to 40° C.

In the surface treatment operation, an oxidizer solution may be injected to the surface of the light shielding film for surface treatment of the light shielding film. The oxidizer solution is a solution having reactivity enabling oxidation of a metal film such as a light shielding film. When the oxidizer solution is injected to the surface of the light shielding film, the oxidizer solution reacts with the surface of the light shielding film, and thereby helps the surface of the light shielding film to have a roughness characteristic targeted in the embodiment. Particularly, by controlling the composition, the flow rate, and the method of injection of the oxidizer solution, the shape, size, and distribution of peaks placed on the surface of the light shielding film can be regulated within a range predetermined in the embodiment.

Hereinafter, description of the surface treatment operation will be made in detail.

The surface treatment operation may include a first rinsing process, a surface oxidation treatment process, and a second rinsing process.

In the surface treatment operation, the first rinsing process may be performed for the surface of the light shielding film before operation of the surface oxidation treatment process. In detail, in the first rinsing process, the blank mask may be rotated at a low speed and simultaneously a carbonated water may be injected at a flow rate of 1000 ml/min to 1800 ml/min. Through this, particles absorbed on the surface of the light shielding film can be effectively removed.

In the surface oxidation treatment process, an oxidizer solution may be injected to the surface of the light shielding film.

Any solution having an oxidizing power with respect to a metal film may be applied as the oxidizer solution without limitation. For example, the oxidizer solution may be at least any one between a hydrogen water and SC-1 solution.

When SC-1 solution is applied as the oxidizer solution, the amount of ammonia water within SC-1 solution may be 0.02 volume% or more. The amount of ammonia water may be 0.05 volume% or more. The amount of ammonia water may be 0.1 volume% or more. The amount of ammonia water may be less than 2 volume%.

When SC-1 solution is applied as the oxidizer solution, the amount of hydrogen peroxide may be 1 volume% or less. The amount of the hydrogen peroxide may be 0.5 volume% or less. The amount of the hydrogen peroxide may be 0.1 volume% or less. The amount of the hydrogen peroxide may be 0.01 volume% or more. The amount of the hydrogen peroxide may be 0.05 volume% or more.

The electric conductivity of the SC-1 solution may be 1000 µS/cm or more. The electric conductivity of the SC-1 solution may be 1500 µS/cm or more. The electric conductivity of the SC-1 solution may be 3000 µS/cm or less. The electric conductivity of the SC-1 solution may be 2500 µS/cm or less.

In such a case, by controlling the skewness and shape of the surface of the light shielding film, the phenomenon of diffused reflection of a testing light can be effectively suppressed when optical properties are measured.

The oxidizer solution may be injected at a total flow rate of 500 ml/min to 4000 ml/min. The oxidizer solution may be injected at a total flow rate of 700 ml/min to 3000 ml/min. The oxidizer solution may be injected at a total flow rate of 1000 ml/min to 2000 ml/min.

When two different solutions are applied as the oxidizer solution, respective solutions may be injected at the same time. When two different solutions are applied as the oxidizer solution, respective solution may be injected in order.

The oxidizer solution may be injected for a duration of 100 seconds to 2000 seconds. The oxidizer solution may be injected for a duration of 200 seconds to 1500 seconds. The oxidizer solution may be injected for a duration of 300 seconds to 1000 seconds. The oxidizer solution may be injected for a duration of 400 seconds to 700 seconds.

In such a case, control of surface roughness of the light shielding film can be effectively achieved.

The oxidizer solution may be a single solution or may be two or more solutions. When two or more solutions are applied as the oxidizer solution, respective solutions may be injected to the surface of the light shielding film by using a separate nozzle.

When two or more solutions are applied as the oxidizer solution, the injection time per solution may be equivalent from each other. The injection time per solution may be different from each other.

To inject the oxidizer solution at uniform flow rate to the entire surface of the light shielding film, the oxidizer solution may be injected while moving the position of an injection nozzle within the surface of the light shielding film during the surface oxidation treatment process.

After completion of the surface oxidation treatment process, the second rinsing process may be performed. In detail, in the second rinsing process, the blank mask may be rotated at a low speed and simultaneously a carbonated water may be injected to the surface of the light shielding film at a flow rate of 1000 ml/min to 1800 ml/min. Through this, the oxidizer solution remaining on the surface of the light shielding film can be effectively removed.

### Manufacturing Method of Semiconductor Element

A manufacturing method of a semiconductor element according to another embodiment of the present disclosure includes preparation of disposing a light source, a photomask, and a semiconductor wafer where a resist film have been applied, an exposure operation of selectively transmitting a light incident from the light source through the photomask to be transferred and a development operation of developing a pattern on the semiconductor wafer.

The photomask includes a transparent substrate and a light shielding pattern film disposed on the transparent substrate.

The light shielding pattern film includes a transition metal, and at least any one between oxygen and nitrogen.

An optical density is measured ten time by a light with a wavelength of 193 nm, a standard deviation of measured values for optical density is 0.009 or less.

A value of subtracting the minimum value from the maximum value among the measured values for optical density is less than 0.03.

The upper surface of the light shielding pattern film has an Rsk (skewness) value of -2 to -0.1.

In the preparation, the light source is a device, which can generate an exposure light with a short wavelength. The exposure light may be a light with a wavelength of 200 nm or less. The exposure light may be ArF light with the wavelength of 193 nm.

A lens may be additionally disposed between the photomask and the semiconductor wafer. The lens has a function of minimizing a circuit pattern shape on the photomask to transfer it on the semiconductor wafer. Any lens applicable to the exposure process for ArF semiconductor wafer in conventional technics may be applied without limitation. For example, the lens may be a lens composed of calcium fluoride (CaF₂).

In the exposure operation, the exposure light may be selectively transmitted on the semiconductor wafer through a photomask. In such a case, in a portion where the exposure light is incident within a resist film, chemical modification may occur.

In the development operation, the semiconductor wafer after the exposure operation is treated with a developing solution to develop a pattern on the semiconductor wafer. When the applied resist film is a positive resist, the position where an exposure light is incident within the resist film may be dissolved by a developing solution. When the applied resist film is a negative resist, the position where an exposure light is not incident may be dissolved by a developing solution. The resist film is formed into a resist pattern by treatment with a developing solution. By taking the resist pattern as a mask, a pattern may be form on the semiconductor wafer.

Description of the photomask is overlapped with the above description and omitted.

Hereinafter, more detailed description of detailed examples will be made.

### Manufacture Example: Formation of Light Shielding Film

Example 1: A transparent substrate made from a quartz material with the width of 6 inches, the length of 6 inches, and the thickness of 0.25 inches was disposed in a chamber of DC sputtering apparatus. A chrome target was disposed in the chamber to form the T/S distance of 255 mm, the angle between the substrate and the target of 25 degrees.

Thereafter, an atmosphere gas, which is a mixture of Ar of 21 volume%, N₂ of 11 volume%, CO₂ of 32 volume%, and He of 36 volume%, was introduced into the chamber, the electric power supplied to a sputtering target was 1.85 kW, and a sputtering process was performed for 250 seconds, thereby forming a first light shielding layer.

After completion of the first light shielding layer, an atmosphere gas, which is a mixture of Ar of 57 volume% and N₂ of 43 volume%, was introduced into the chamber, the electric power supplied to a sputtering target was 1.5 kW, and a sputtering process was performed for 25 seconds, thereby manufacturing a blank mask sample, on which a second light shielding layer had been formed.

The sample after the formation of the second light shielding layer was disposed in a thermal treatment chamber, and thermal treatment was performed for 15 minutes at an atmosphere temperature of 200° C.

A cooling plate, whose cooling temperature had been applied to be 23° C., was equipped in the side of the substrate of the sample after thermal treatment. The distance between the substrate and the cooling plate of the sample was regulated to have the cooling speed of 45° C./min, and the cooling operation was performed for 5 minutes.

After the cooling treatment, the sample was stabilized for 120 minutes by the method of keeping the sample in an atmosphere at a temperature of 20° C. to 25° C.

The first rinsing process was performed to the light shielding film of the sample after stabilization. In detail, while the sample was rotated at a low speed, a carbonated water in a flow rate of 1000 ml/min to 1800 ml/min was injected to the surface of the light shielding film of the same for 80 seconds to perform rinsing.

After completion of the first rinsing process, a surface oxidation treatment process was performed on the surface of the light shielding film of the sample. In detail, SC-1 solution in a flow rate of 500 ml/min to 1000 ml/min and a hydrogen water in a flow rate of 500 ml/min to 1500 ml/min were injected to the surface of the light shielding film at the same time for 504 seconds as the oxidation solution. Subsequently, a hydrogen water in a flow rate of 500 ml/min to 1500 ml/min was injected alone to the surface of the light shielding film for 160 seconds.

The SC-1 solution has ammonia water (NH₄OH) in the amount of 0.1 volume% and hydrogen peroxide (H₂O₂) in the amount of 0.08 volume%.

In the process of injecting the SC-1 solution and hydrogen water, an injecting nozzle was repetitively moved in the diagonal direction while injection was performed.

Thereafter, the sample was rotated at a low speed and a carbonated water in a flow rate of 1000 ml/min to 1800 ml/min was injected to the surface of the light shielding film of the sample for 88 seconds to perform the second rinsing process.

Example 2: A blank mask sample was manufactured under the same condition as Example 1. However, in the surface oxidation treatment process, the amount of ammonia water (NH₄OH) within SC-1 solution was applied to be 0.15 volume%.

Example 3: A blank mask sample was manufactured under the same condition as Example 1. However, in the surface oxidation treatment process, the amount of ammonia water (NH₄OH) within SC-1 solution was applied to be 0.05 volume%.

Example 4: A blank mask sample was manufactured under the same condition as Example 1. However, in the surface oxidation treatment process, the amount of ammonia water (NH₄OH) within SC-1 solution was applied to be 0.5 volume%.

Example 5: A blank mask sample was manufactured under the same condition as Example 1. However, in the surface oxidation treatment process, the amount of ammonia water (NH₄OH) within SC-1 solution was applied to be 0.07 volume%.

Comparative Example 1: A blank mask sample was manufactured under the same condition as Example 1. However, after the stabilization treatment, the first rinsing process, surface oxidation treatment process, and second rinsing process were not applied.

Comparative Example 2: A blank mask sample was manufactured under the same condition as Example 1. However, in the surface oxidation treatment process, a carbonated water in a flow rate of 1000 ml/min to 2500 ml/min was injected instead of the oxidizer solution.

Comparative Example 3: A blank mask sample was manufactured under the same condition as Example 1. However, in the surface oxidation treatment process, the amount of ammonia water within SC-1 solution was applied to be 2 volume%.

Comparative Example 4: A blank mask sample was manufactured under the same condition as Example 1. However, in the thermal treatment process, the temperature for thermal treatment was applied to be 150° C., and the cooling temperature was applied to be 27° C. in the cooling process.

Comparative Example 5: A blank mask sample was manufactured under the same condition as Example 1. However, the stabilization process was performed for 20 minutes.

The process condition of each Example or Comparative Example was described in Table 1 below.

### Evaluation of Examples: Evaluation for Deviation in Optical Properties

On the surface of the light shielding film of each Example or Comparative Example, a measuring area with the width of 132 mm and the length of 132 mm placed on the center of the light shielding film was selected. Total 36 sectors formed by dividing the measuring area into six portions vertically and horizontally were selected. Total 49 vertices of respective sectors were selected as measuring points, thereby a transmittance value was measured at each measuring point by using a spectroscopic ellipsometer, and the optical density of Equation 1 was calculated from the transmittance value. The average value of optical density values of respective measuring points was calculated, and the value was considered as the optical density value of the light shielding film.

For calculating the standard deviation of optical density values and a value of subtracting the minimum value from the maximum value among the values, the optical density of the light shielding film was measured ten times. All the processes of measuring the optical density of the light shielding film ten times were performed at the same measuring points in the same measuring conditions.

MG-Pro available from NANO-VIEW CO., LTD was used as the spectroscopic ellipsometer, and the wavelength of the testing light was 193 nm.

Through the same method as the method of calculating the standard deviation of optical density values and a value of subtracting the minimum value from the maximum value among the values, the standard deviation of transmittance and reflectance and a value of subtracting the minimum value from the maximum value among the values were calculated.

The measured value of each Example or Comparative Example was described in Table 2 below.

### Evaluation of Examples: Evaluation for Surface Roughness

Rsk, Rku, Rp, and Rv values of the surface of the light shielding film of each Example or Comparative Example were measured in accordance with ISO_4287. Rpv value was calculated by the sum of the Rp value and the Rv value.

In detail, in an area of 1 µm vertically and horizontally, Rsk, Rku, Rp, Rv, and Rpv values were measured in Non-contact mode at a scan speed of 0.5 Hz by using XE-150 model available from Park System corporation applied with PPP-NCHR as Cantilever model available from Park System as a probe.

The measured result of each Example and Comparative Example was described in Table 3 below.

TABLE 1

| | Tempera ture for Thermal Treatme nt (°C) | Cooling Speed (°C/min) | Stabilizat ion time (min) | The Amount of Ammonia Water within SC-1 Solution (Volume%) | The Flux of SC-1 Solution (ml/min) | The Flux of Hydrogen Water (ml/min) | Whether First and Second Rinsing Processes Are Performed |
|---|---|---|---|---|---|---|---|
| Exampl e 1 | 250 | 45 | 120 | 0.1 | 500~1000 | 500~1500 | O |
| Exampl e2 | 250 | 45 | 120 | 0.15 | 500~1000 | 500~1500 | O |
| Exampl e 3 | 250 | 45 | 120 | 0.05 | 500~1000 | 500~1500 | O |
| Exampl e 4 | 250 | 45 | 120 | 0.5 | 500~1000 | 500~1500 | O |
| Exampl e 5 | 250 | 45 | 120 | 0.07 | 500~1000 | 500~1500 | O |
| Compar ative Exampl e 1 | 250 | 45 | 120 | - | - | - | X |
| Compar ative | 250 | 45 | 120 | - | - | - | O |
| Exampl e2 | | | | | | | |
| Compar ative Exampl e 3 | 250 | 45 | 120 | 2 | 500~1000 | 500~1500 | O |
| Compar ative Exampl e 4 | 150 | 27 | 120 | 0.1 | 500~1000 | 500~1500 | O |
| Compar ative Exampl e5 | 250 | 45 | 20 | 0.1 | 500~1000 | 500~1500 | O |

TABLE 2

| | Standard Deviation | | | A Value of Subtracting the Minimum value from the Maximum Value | | |
|---|---|---|---|---|---|---|
| | Optical Density | Transmittanc e (%) | Reflectance (%) | Optical Density | Transmittanc e (%) | Reflectance (%) |
| Example 1 | 0.0049 | 0.00092 | 0.0245 | 0.016 | 0.0030 | 0.0813 |
| Example 2 | 0.0050 | 0.00094 | 0.0249 | 0.016 | 0.0030 | 0.0814 |
| Example 3 | 0.0053 | 0.00099 | 0.0272 | 0.017 | 0.0032 | 0.0851 |
| Example 4 | 0.0052 | 0.00098 | 0.0271 | 0.017 | 0.0032 | 0.0849 |
| Example 5 | 0.0051 | 0.00095 | 0.0254 | 0.016 | 0.0031 | 0.0827 |
| Comparati ve Example 1 | 0.0101 | 0.00190 | 0.0400 | 0.033 | 0.0061 | 0.1271 |
| Comparati ve Example 2 | 0.0093 | 0.00182 | 0.0328 | 0.030 | 0.0058 | 0.0994 |
| Comparati ve | 0.0103 | 0.00195 | 0.0422 | 0.033 | 0.0062 | 0.1273 |
| Example 3 | | | | | | |
| Comparati ve Example 4 | 0.0101 | 0.00192 | 0.0417 | 0.034 | 0.0061 | 0.1296 |
| Comparati ve Example 5 | 0.0099 | 0.00189 | 0.0387 | 0.032 | 0.0060 | 0.1198 |

TABLE 3

| | Rsk | Rku | Rp(nm) | Rv(nm) | Rpv(nm) |
|---|---|---|---|---|---|
| Example 1 | -0.876 | 2.715 | 4.289 | 3.072 | 7.361 |
| Example 2 | -0.708 | 2.837 | 4.694 | 3.144 | 7.838 |
| Example 3 | -0.205 | 2.962 | 4.630 | 3.590 | 8.220 |
| Example 4 | -0.318 | 3.199 | 4.450 | 3.896 | 8.346 |
| Example 5 | -0.686 | 2.849 | 4.452 | 3.466 | 7.918 |
| Comparati ve Example 1 | 0.599 | 4.176 | 4.816 | 3.751 | 8.567 |
| Comparati ve Example 2 | 0.278 | 3.663 | 4.694 | 3.844 | 8.538 |
| Comparati ve Example 3 | 0.399 | 4.048 | 5.894 | 3.023 | 8.917 |
| Comparati ve Example 4 | 0.457 | 3.894 | 4.791 | 3.854 | 8.645 |
| Comparati ve Example 5 | 0.294 | 3.514 | 4.743 | 3.789 | 8.532 |

In the Table 2, the standard deviation of optical density in Examples 1 to 5 was 0.009 or less as measured. On the other hand, the standard deviation of optical density in Comparative Examples 1 to 5 was more than 0.009 as measured.

The standard deviation of reflectance in Examples 1 to 5 was 0.032% or less as measured. On the other hand, the standard deviation of reflectance in Comparative Examples 1 to 5 was more than 0.032% as measured.

A value of subtracting the minimum value from the maximum value among optical density values in Examples 1 to 5 was 0.02 or less as measured. On the other hand, the value in Comparative Examples 1 to 5 was more than 0.03 as measured.

A value of subtracting the minimum value from the maximum value among reflectance values in Examples 1 to 5 was 0.09% or less as measured. On the other hand, the value in Comparative Examples 1 to 5 was more than 0.09% as measured.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A blank mask comprising a transparent substrate and a light shielding film disposed on the transparent substrate,
wherein the light shielding film comprises a transition metal and at least one selected from the group consisting of oxygen and nitrogen, and
wherein when an optical density of the light shielding film is measured ten times by a light with a wavelength of 193 nm, a standard deviation of measured optical density is 0.009 or less.

2. The blank mask of claim 1, wherein a value obtained by subtracting a minimum value of the measured optical density from a maximum value of the measured optical density is less than 0.03.

3. The blank mask of claim 1, wherein a surface of the light shielding film has an Rsk value, which is a height skewness of the surface of the light shielding film, of -2 to 0.1.

4. The blank mask of claim 1, wherein the measured optical density is an average value of optical density values measured at a total of 49 measuring points on the surface of the light shielding film, respectively, and
wherein a total of ten measured optical densities are obtained by repeating ten times of measuring at the total of 49 measuring points on the surface of the light shielding film, respectively, wherein, in each of the ten measurement, the total of 49 measuring points are same.

5. The blank mask of claim 1, wherein when a reflectance of the light shielding film is measured ten times by a light with a wavelength of 193 nm, a standard deviation of measured reflectance values is 0.032% or less, and
wherein a value obtained by subtracting a minimum value of the measured reflectance values from a maximum value of the measured reflectance values is 0.09% or less.

6. The blank mask of claim 1, wherein a reflectance value of the light shielding film with respect to a light with a wavelength of 190 nm to 550 nm is 15% to 35%.

7. The blank mask of claim 1, wherein a Rku, which is kurtosis, of the surface of the light shielding film is 3.5 or less.

8. The blank mask of claim 1, wherein a Rp, which is a maximum height of a peak, of the surface of the light shielding film is 4.7 nm or less.

9. The blank mask of claim 1, wherein a Rpv, which is a sum of maximum height of a peak and maximum depth of a valley, of the surface of the light shielding film is 8.5 nm or less.

10. The blank mask of claim 1, wherein the light shielding film comprises a first light shielding layer and a second light shielding layer disposed on the first light shielding layer, and
wherein the second light shielding layer has a greater amount of the transition metal than the first light shielding layer.

11. The blank mask of claim 1, wherein the transition metal comprises at least one selected from the group consisting of Cr, Ta, Ti, and Hf.

12. A photomask comprising a transparent substrate and a light shielding pattern film disposed on the transparent substrate,
wherein the light shielding pattern film comprises a transition metal and at least one selected from the group consisting of oxygen and nitrogen, and
wherein when an optical density of an upper surface of the light shielding pattern film is measured ten times by a light with a wavelength of 193 nm, a standard deviation of measured optical density is 0.009 or less.

13. The photomask of claim 12, wherein a value obtained by subtracting a minimum value of the measured optical density from a maximum value of the measured optical density is less than 0.03.

14. The photomask of claim 12, wherein the upper surface of the light shielding pattern film has an Rsk value, which is a height skewness of the surface of the light shielding pattern film, of -2 to 0.1.

15. A method of manufacturing a blank mask comprising:
disposing a transparent substrate and a sputtering target inside a sputtering chamber;
injecting an atmosphere gas into the sputtering chamber and supplying an electric power to the sputtering target to form a light shielding film on the transparent substrate;
thermally treating the light shielding film;
cooling the light shielding film;
stabilizing the blank mask after the cooling operation in an atmosphere; and
treating a surface of the light shielding film.

16. The method of claim 15, wherein the treating the surface of the light shielding film comprises a surface oxidation treatment process of applying an oxidizer solution to the surface of the light shielding film.

17. The method of claim 15, further comprising a rinsing process of performing rinsing to the surface of the light shielding film.

18. The method of claim 16, wherein the oxidizer solution comprises at least one selected from the group consisting of a hydrogen water and SC-1 solution.

19. The method of claim 18, wherein an amount of ammonia water within SC-1 solution is 0.02 volume% to 2 volume% based on a total volume of the SC-1 solution.

20. The method of claim 15, wherein the light shielding film is thermally treated at a temperature of 160 to 300° C. for 5 to 30 minutes.
